(19) United States
(12) Patent Application Publication
(10) Pub. No.: US 2002/0130361 A1
(43) Pub. Date: Sep. 19, 2002

(54) Semiconductor device with laterally varying p-top layers

(75) Inventors: Mohamed Imam, Tempe, AZ (US); Evgueniy N. Stefanov, Vieille Toulouse (FR); Zia Hossain, Tempe, AZ (US); Mohammed Tanvir Quddus, Tempe, AZ (US); Joe Fulton, Chandler, AZ (US)

Correspondence Address: Robert D. Atkins, ON Semiconductor, Patent Administration Dept-MD A230, P.O. Box 62890, Phoenix, AZ, 85082-2890, US

(73) Assignee: Semiconductor Components Industries, LLC

(21) Appl. No.: 09/808,964

(22) Filed: Mar. 16, 2001

(51) Int. Cl. H01L 29/76; H01L 29/94; H01L 31/062

(52) U.S. Cl. 257/341; 257/328; 257/335; 257/345

(57) ABSTRACT

A high voltage MOS device (100) is disclosed. The MOS device comprises an n-well region (113) with a top layer (108) of opposite conductivity. The doping in the top layer (108) varies laterally, increasing breakdown voltage and decreasing on-resistance.

### FIELD OF THE INVENTION

The present invention relates to high voltage MOS devices and more specifically to a high voltage MOS device with laterally varying p-region.

### BACKGROUND OF THE INVENTION

When designing high voltage metal oxide (MOS) devices two criteria must be kept in mind. First, the device should have a very high breakdown voltage (V_{BD}) Second, the device, when operating, should have as low an on-resistance (RDS_{ON}) as possible. One problem is that techniques and structures that tend to maximize V_{BD} tend to adversely affect RDS_{ON} and vice versa.

To overcome this problem, different designs have been proposed to form devices with acceptable combinations of V_{BD} and RDS_{ON}. One such family of devices is fabricated according to the reduced surface field (RESURF) principle. These devices utilize an extended drain region (in one embodiment a n-well) to support high off-state voltage (V_{BD}). These devices have a maximum number of charges in the drain area of about 1×10¹² cm⁻² before avalanche breakdown occurs. This maximum charge sets the lowest RDS_{ON} since RDS_{ON} is proportional to the charge in the drain region.

To help alleviate this problem, some devices utilize a top layer of a conductivity type opposite the extended drain region (in one embodiment a p-type layer) inside the drain region. The top layer allows for a drain region having approximately double the charge than previous designs, which decreases RDS_{ON}. The top layer helps to deplete the extended drain when the device is supporting high voltage, thus allowing for high breakdown voltage. P-top layers are typically formed at the top of the device via an implantation and heat cycle. The result is a p-top region having uniform doping concentration throughout. While this additional layer is beneficial, a uniform p-top region may not always optimize device characteristics.

### BRIEF DESCRIPTION OF THE DRAWINGS

For a more complete understanding of the present invention and advantages thereof, reference is now made to the following descriptions, taken in conjunction with the following drawings, in which like reference numerals represent like parts, and in which:

FIG. 1 is a cross-sectional side view of the device;

FIG. 2 is a cross-sectional side view showing the formation of a p-top layer having a laterally varying doping;

FIG. 3 is a cross-sectional side view of the device with an enhanced n-well;

FIG. 4 is a cross-sectional view of the device with multiple p-top layers;

FIG. 5a is an overhead view of a cross-section of device;

FIG. 5b is an overhead view of a cross-section of the device with the p-top layer formed as stripes parallel to current flow; and

FIG. 5c is an overhead view of a cross-section of the device with the p-top layers formed as stripes perpendicular to current flow.

### DETAILED DESCRIPTION OF THE DRAWINGS

The present invention relates to high voltage MOS devices that have a high breakdown voltage and low on-resistance. While specific embodiments are described below using n-channel devices, the present invention also pertains to p-channel devices, which may be formed by reversing the conductivity of the described regions and layers.

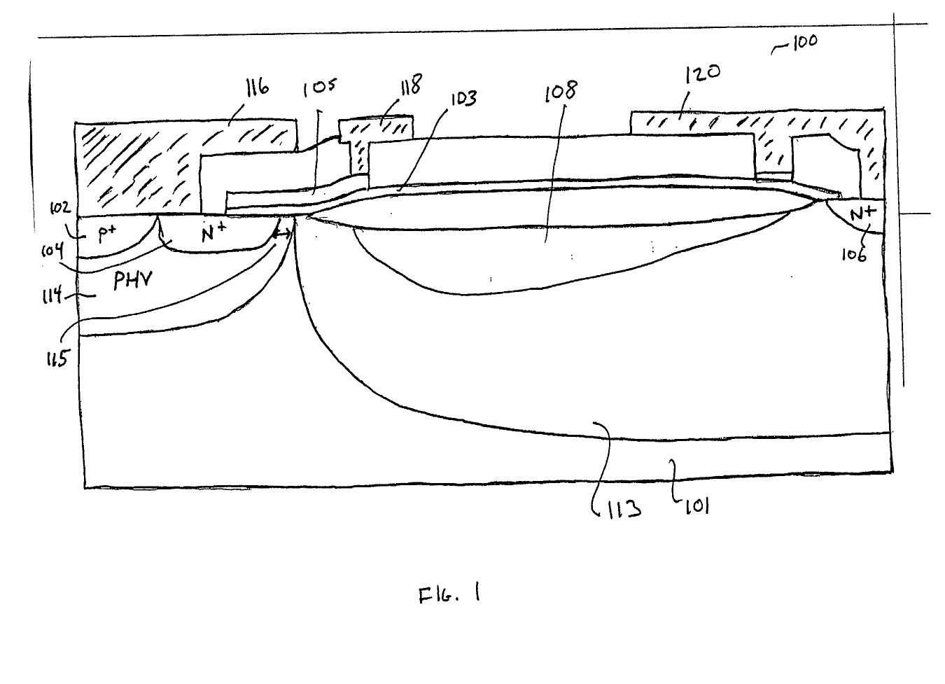

FIG. 1 is a cross-sectional side view of an n-channel MOS device 100 with laterally varying p-regions. Illustrated is a lightly doped p-type substrate region 101. An N+ source diffusion region 104 is formed in substrate region 101. A P+ diffusion region 102 is formed adjacent to N+ source diffusion region 104. The P+ diffusion region 102, increases the integrity of the source to substrate connection as well as reduces the device's susceptibility to parasitic bipolar effects. Associated with N+ source diffusion region 104 and P+ diffusion region 102 is a source electrode 116, which provides electrical contact to the N+ source region 104 and the P+ region 102. Also illustrated is a gate 105 (typically comprising polysilicon) formed over an insulating layer 103 (comprising silicon dioxide or some other insulating dielectric material) and a gate contact 118.

A drain diffusion region 106 is connected electrically to drain contact 120. Drain contact 120 may comprise a number of conductive metals or metal alloys. An optional diffused P region 114 may be formed to enclose P+ region 102 and N+ source region 104. The diffused P region 114 is a lightly doped (high voltage) P-region (PHV) and helps to reduce the device's susceptibility to drain-to-source punch through as well as helps to provide an appropriate threshold voltage. When the source contact and drain contact are on the same surface, the device with the diffused P region 114 is a lateral double diffused metal oxide (LDMOS) device. A channel region 115 exists at the top of the substrate 101 from the N+ source region 104 to the end of the diffusion region 114.

An n-well region 113 is formed in substrate 101. N-well 113 is formed via implanting dopants. In n-well 113, in one embodiment, the number of charges can approach 2×10¹² cm⁻². While an n-well region 113 is shown, the region may also be a n-epi layer formed by epitaxial growth. A field oxide layer 107 is formed over n-well 113 to protect the n-well 113 from mobile contaminants.

A p-top layer 108 is formed inside n-well 113 for charge balancing. In the present invention, p-top layer 108 has a doping concentration that laterally varies along the p-top layer. As can be seen in FIG. 1, as p-top layer 108 approaches the drain region, the thickness of the p-top layer decreases uniformly. The uniformly, laterally varying doping leads to more uniform electrical fields, which results in a higher breakdown voltage. Additionally, RDS_{ON} is decreased by providing p-top layer 108. In another embodiment, the orientation of the p-top layer 108 can be reversed with the thickness decreasing from the drain to the source. P-top layer 108 can be connected to ground or left floating.

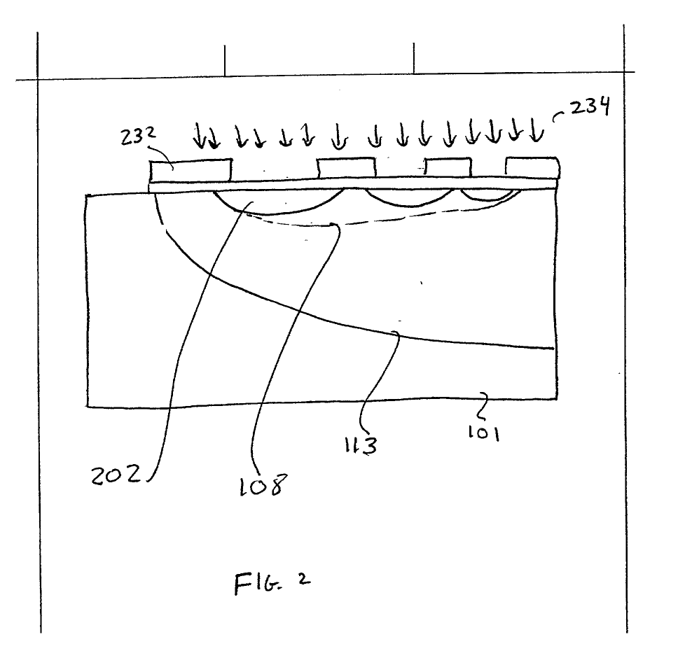

FIG. 2 is a cross-sectional side view showing the formation of a p-top layer 108 having a laterally varying doping. FIG. 2 illustrates substrate 101 with an n-well 113 (or n-epi layer) formed within the substrate 101. A layer of pad oxide 230 is applied over the substrate 101. On top of that a mask 232 of photoresist is applied. The size of the openings in mask 232 decreases laterally. Next an implant 234 (typically of boron) is done through the openings in mask 232. Where there is an opening, p-top layers 202 will form. Different size p-top layers will be formed with large p-top layers corresponding to the larger openings in the mask 232. After heat treatment, the doping concentration in p-top layers will decrease laterally from the part of the p-top layer closest to the source region to the portion closer to the drain region. Individual p-regions will diffuse to form p-top layer 108 as seen as a dotted line in FIG. 2. While P-top layer 108 in FIG. 1 is seen at the surface of substrate 101, p-top layer 108 could be formed inside n-well 113 by using a higher energy implant.

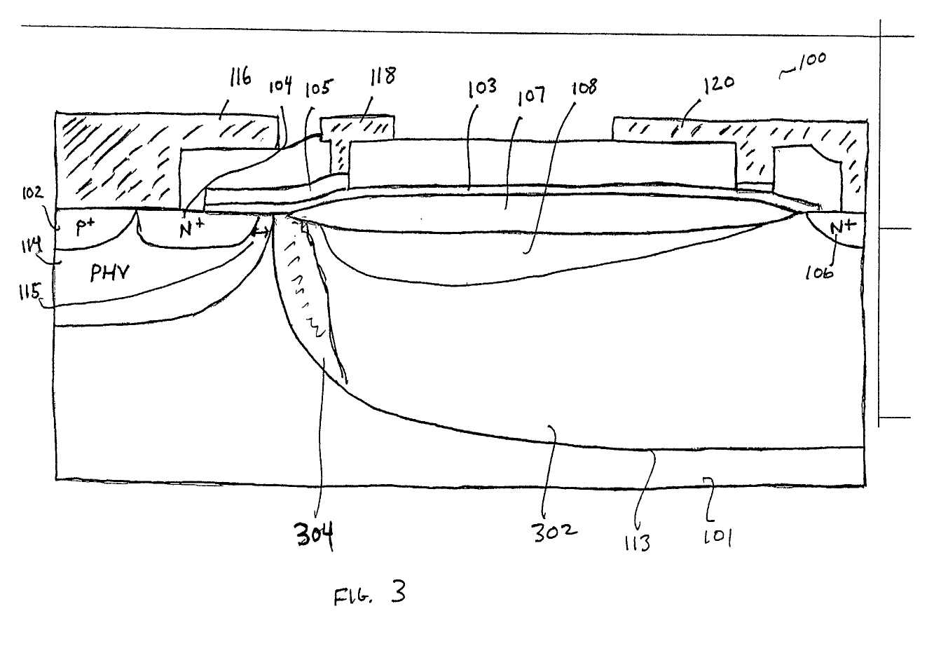

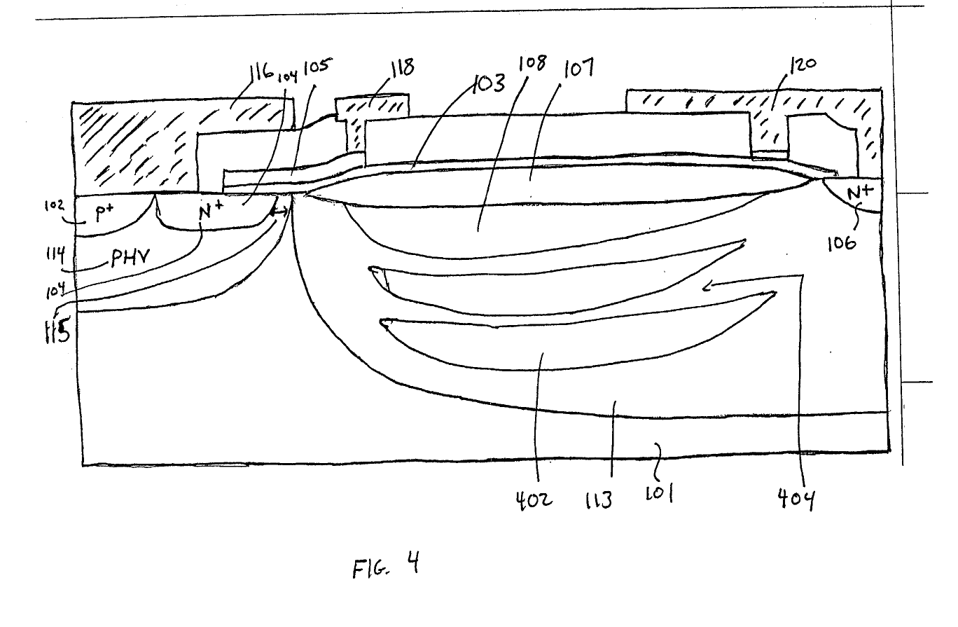

FIG. 3 is a cross sectional view of the device with an enhanced n-well 113. As shown in FIG. 4, n-well 113 comprises a first region 302 of high dopant concentration offset from a second region 304 of lower dopant concentration. The regions are formed by performing two separate n-well implants. The first implant is a relatively low concentration implant. Then, a second implant of higher concentration is performed. The second implant is laterally offset from the first implant by a certain amount, n-well 113 forming the two separate regions. The two regions allow for a lower concentration of dopants under the gate region and adjacent to the diffused P+ region 114 and the channel region 115, which increases the depletion extension into the n-well 113 between the n+source region 104 and the n-well 113, which helps prevent premature breakdowns that occur at critical fields at the surface of the device.

FIG. 4 is a cross-sectional view of the device with multiple p-top layers. As seen in FIG. 4, additional p-regions 402 are formed within n-well 113 and below p-top layer 108. These p-regions are formed, for example, by high-energy ion implantation. The result is a n-well 113 with multiple p-regions 402 separated by conduction channels 404. The additional conduction channels allows for a lower on resistance by allowing for a large charge in each conduction channel.

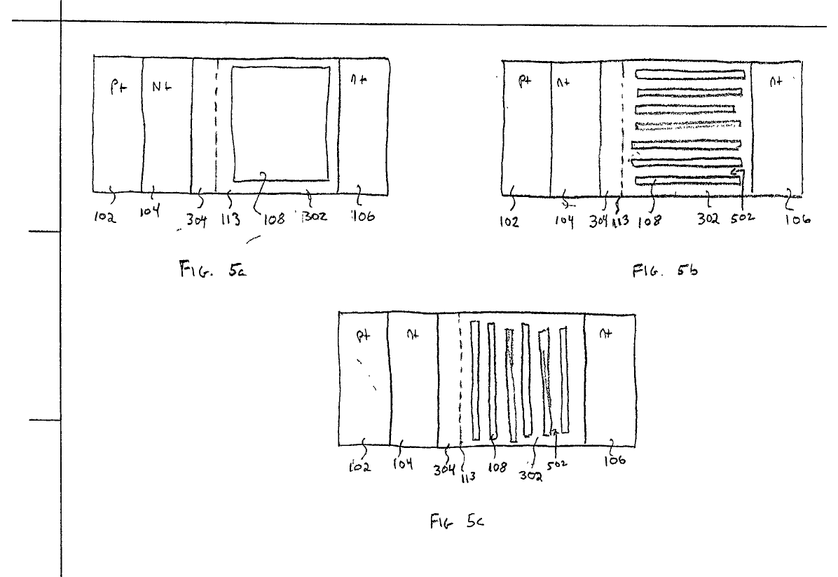

FIG. 5a is a cross-sectional view of device 100. Illustrated is the source region 104, the adjacent p-region 102, a drain region 106 and p-top layer 108, which, in this embodiment, is one solid p-top layer 108. P-top layer 108 overlies n-well 113, which, in this illustration overlies the first region 112 of higher concentration and a second region 110 of lower concentration. Of course, in this invention, p-top layer 108 can be formed in a conventional n-well 113 as well. As discussed in conjunction with FIG. 4, there can be multiple p-regions under the p-top layer 108. P-top layer 108 also is not necessary at the top but can be below the surface of the n-well 113.

FIG. 5b represents the device 100 but with p-top top layer 108 comprising multiple “stripes” of p-top layer 108 each one separated by a conduction channel which is parallel to current flow (current will flow from the source to the drain). FIG. 5b also illustrates n-well 113 having a first region of high dopant concentration 112 and a second region of lower dopant concentration.

FIG. 5c shows a device similar to the device in FIG. 5b except the “stripes” of p-top layers 108 are aligned perpendicular to current flow. Again, n-well 113 is illustrated having a first region of high dopant concentration 112 and a second region of low dopant concentration 110.

Thus, it is apparent that there has been provided, an improved semiconductor device. It should be understood that various changes, substitutions, and alterations are readily ascertainable and can be made herein without departing from the spirit and scope of the present invention as defined by the following claims.

What is claimed

1. A high voltage MOS device comprising;
a substrate;
a first region of a first conductivity type formed in the substrate; and
at least one second region of a second conductivity type formed in the first region wherein at least one second region of the second conductivity type has doping which varies laterally.

2. The device of claim 1, wherein the at least one second region has a higher doping concentration near a source region and a lower concentration near a drain region and the doping varies laterally between the source region and the drain region.

3. The device of claim 1, wherein the first region is an epitaxial region.

4. The device of claim 1, wherein the first region is a well region formed by ion implantation.

5. The device of claim 4, wherein the well region comprises a first area of high concentration of dopants and a second area of low concentration of dopants.

6. The device of claim 5, wherein the second area of low concentration underlies a gate region adjacent to a channel region.

7. The device of claim 1, wherein at least one second region of a second conductivity type is a plurality of laterally varying regions distributed throughout layers of the first region and separated by conductivity channels.

8. A method for manufacturing a high voltage MOS device comprising:
providing a substrate;
providing a first region of a first conductivity type in the substrate;
providing a mask with openings that decrease in width laterally across the mask;
implanting impurities of a second conductivity type through the openings in the mask; and
forming a second region of a second conductivity type, the second region having a laterally varying doping profile.

9. The method of claim 8, wherein the step of forming a second region further comprising forming a higher doping concentration near a source region and a lower doping concentration near the drain region and wherein the doping concentration varies laterally from the source region to the drain region.

10. The method of claim 8, wherein the step of providing a first region further comprises forming an epitaxial region.

11. The method of claim 8, wherein the step of providing a first region further comprising forming a well region.

12. The method of claim 11, wherein the step of providing a well region further comprises forming a first area of high concentration of dopants and a second area of low concentration of dopants.

13. The method of claim 12, wherein the step of forming a first region of high concentration further comprises forming a second area of low concentration underlying a gate region adjacent to a channel region.

14. The method of claim 8, wherein the step of forming a second region further comprises forming a plurality of laterally varying regions.

15. The method of claim 8, wherein the step of forming a second region further comprises forming a plurality of laterally varying regions distributed throughout layers of the first region and separated by conductivity channels.

16. A high voltage DMOS device comprising:
a substrate;
a first region of a first conductivity type formed in the substrate;
a second region of a second conductivity type formed in the first region, the second region having a doping concentration that varies laterally;
a drain region formed within the first region;
a third region of the second conductivity type, the third region being a lightly doped, high voltage region; and
a source region formed within the third region.

17. The device of claim 16, wherein the second region has a higher doping concentration near a source region and a lower doping concentration near the drain region and the doping concentration varying laterally from the area near the source region to the area near the drain region.

18. The device of claim 16, wherein the first region is an epitaxial region.

19. The device of claim 16, wherein the first region is a well region.

20. The device of claim 19, wherein the well region comprises a first area of high concentration of dopants and a second area of low concentration of dopants.

21. The device of claim 22, wherein the second area of low concentration of dopants underlies a gate region adjacent to a channel region.

22. The device of claim 16, wherein the second region comprises a plurality of laterally varying regions.

23. The device of claim 16, wherein the second region is a plurality of laterally varying regions distributed throughout layers of the first region and separated by conductivity channels.

24. A high voltage MOS device comprising;
a substrate;
a first region formed in the substrate by implanting dopants of a first conductivity type; and
a second region formed in the first region by implanting dopants of a second conductivity type whose concentration varies laterally.

25. The device of claim 24, wherein the second region has a higher doping concentration near a source region and a lower doping concentration near a drain region and the doping varying laterally between the source region and the drain region.

26. The device of claim 24, wherein the first region comprises a first area of high concentration of dopants and a second area of low concentration of dopants.

27. The device of claim 28, wherein the second area of low concentration of dopants underlies a gate region adjacent to a channel region.

28. The device of claim 24, wherein the second region is a plurality of laterally varying regions distributed throughout vertical layers of the first region and separated by conductivity channels.
